(19) United States
(12) Patent Application Publication
(10) Pub. No.: US 2014/0110245 A1
(43) Pub. Date: Apr. 24, 2014

(54) NON-BONDED ROTATABLE TARGETS AND THEIR METHODS OF SPUTTERING

(71) Applicant: PRIMESTAR SOLAR, INC., Arvada, CO (US)

(72) Inventors: Robert Dwayne Gossman, Aurora, CO (US); Scott Daniel Feldman-Peabody, Golden, CO (US); Russell Weldon Black, Longmont, CO (US)

(73) Assignee: PrimeStar Solar, Inc., Arvada, CO (US)

(21) Appl. No.: 13/654,470

(22) Filed: Oct. 18, 2012

(51) Int. Cl. C23C 14/34

(52) U.S. Cl. 204/192.12; 204/298.12

(57) ABSTRACT

Cylindrical sputtering targets, along with methods of their manufacture and use, are provided. The cylindrical sputtering target includes a tubular member having a length in a longitudinal direction and defining a tube surface, and a source material positioned about the tube surface of the tubular member and forming a sputtering surface about the tubular member. The source material generally defines an inner surface opposite of the sputtering surface and non-bonded to the tube surface of the tubular member. The inner surface of the source material is mechanically engaged to the tube surface of the tubular member, and/or the source material can include a first cylindrical ring directly stacked onto a second cylindrical ring with the first cylindrical ring being mechanically engaged to the second cylindrical ring.

### FIELD OF THE INVENTION

The subject matter disclosed herein relates generally to non-bonded, cylindrical sputtering targets and their use during deposition of a thin film layer on a substrate.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials.

The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type layer (i.e., an electron accepting layer) and the CdS layer acts as a n-type layer (i.e., an electron donating layer). Free carrier pairs are created by light energy and then separated by the p-n heterojunction to produce an electrical current.

The CdS layer, along with other layers (e.g., a transparent conductive oxide layer of cadmium tin oxide) can be formed via a sputtering process (also know as physical vapor deposition) where the source material is supplied from a semiconducting target (e.g., cadmium sulfide, cadmium tin oxide, etc.). Typically, the cadmium sulfide semiconducting target is bonded to a backing plate that is water cooled and then placed into magnetrons (cathodes) that perform the sputtering action. The semiconducting target is typically bonded to the backing plate using indium solder or a conductive epoxy. The bond provides good thermal and electrical contact between the semiconducting target and the water cooled backing plate. Thus, the heat created by the plasma on the opposite side of the semiconducting target can be dissipated and carried away from the target by the water cooled backing plate.

As the semiconducting target is sputtered, the semiconducting material is eroded from the target. As the semiconducting target erodes, nodules form on the surface of the target that, over time, may change the deposition rate during sputtering and could affect the characteristics of the resulting thin film. Additionally, these nodules can cause arcs to form in the sputtering chamber. These variables created after sputtering over an extended period can lead to thin film variances of the deposited semiconducting layers in a large-scale, manufacturing environment, such as during the commercial manufacture of cadmium telluride based thin film photovoltaic devices.

Thus, a need exists for a more uniform sputtering process for the deposition of substantially uniform layers.

### BRIEF DESCRIPTION OF THE INVENTION

Aspects and advantages of the invention will be set forth in part in the following description, or may be obvious from the description, or may be learned through practice of the invention.

Cylindrical sputtering targets are generally provided, along with methods of their manufacture and use. For example, the cylindrical sputtering target includes a tubular member having a length in a longitudinal direction and defining a tube surface, and a source material positioned about the tube surface of the tubular member and forming a sputtering surface about the tubular member. The source material generally define an inner surface opposite of the sputtering surface and non-bonded to the tube surface of the tubular member.

In one particular embodiment, the inner surface of the source material is mechanically engaged to the tube surface of the tubular member. Alternatively, or additionally, the source material can include a first cylindrical ring directly stacked onto a second cylindrical ring, with the first cylindrical ring being mechanically engaged to the second cylindrical ring.

In one embodiment, a method is also generally provided for forming a thin film layer on a substrate. The method can include mechanically engaging an inner surface of a source material defining a ring to a tube surface of a tubular member to form a cylindrical target with the source material being positioned about the tube surface of the tubular member and forming a sputtering surface about the tubular member. The inner surface of the source material is positioned opposite of the sputtering surface and non-bonded to the tube surface of the tubular member. The cylindrical target can then be rotated about a center axis, and atoms can be ejected from the sputtering surface with a plasma. A substrate (or a plurality of substrates) can be transported across the plasma at a substantially consistent speed such that the atoms ejected from the sputtering surface deposit onto the substrate to form a thin film layer.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a perspective view of an exemplary cylindrical sputtering target having a source material forming a sputtering surface positioned around a tubular member;

FIG. 2 shows a cross-sectional view of one embodiment of the exemplary cylindrical sputtering target of FIG. 1;

FIG. 3 shows a cross-sectional view of another embodiment of the exemplary cylindrical sputtering target of FIG. 1;

FIG. 4 shows a cross-sectional view of yet another embodiment of the exemplary cylindrical sputtering target of FIG. 1;

FIG. 5 shows a side view of one embodiment of any of the exemplary cylindrical sputtering targets of FIGS. 1-4;

FIG. 6 shows a side view of another embodiment of any of the exemplary cylindrical sputtering targets of FIGS. 1-4; and,

FIG. 7 shows an exemplary sputtering chamber for use with any of the cylindrical sputtering targets of FIGS. 1-6.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Non-bonded, cylindrical sputtering targets are generally provided, along with methods of their use in forming a thin film layer on a substrate. The source material (i.e., the target) is generally non-bonded to the tubular member such that a gap (e.g., a space) is formed between the inner surface of the source material and the tube surface of the tubular member. This gap minimizes thermal conductivity between the source material and the tubular member. As such, during the deposition process under near vacuum conditions, the source material and the tubular member are substantially thermally isolated from each other. This thermal isolation allows the source material to heat during the deposition process, especially in a large-scale manufacturing setting, to raise the surface temperature of the source material.

During use, the cylindrical target is rotated quickly to ensure that the source material is substantially uniformly sputtered from the sputtering surface. Additionally, any inhomogeneities in the cylindrical target can be blurred over very small sections of the deposited thin film layer (e.g., within a monolayer of the thin film layer). As such, a substantially homogeneous thin film layer can be deposited on a substrate via sputtering of the cylindrical target. When utilized in the formation of a thin film layer of a photovoltaic module, the cost per watt of the resulting module can be significantly lowered through this sputtering process due to the maximized use of the source material.

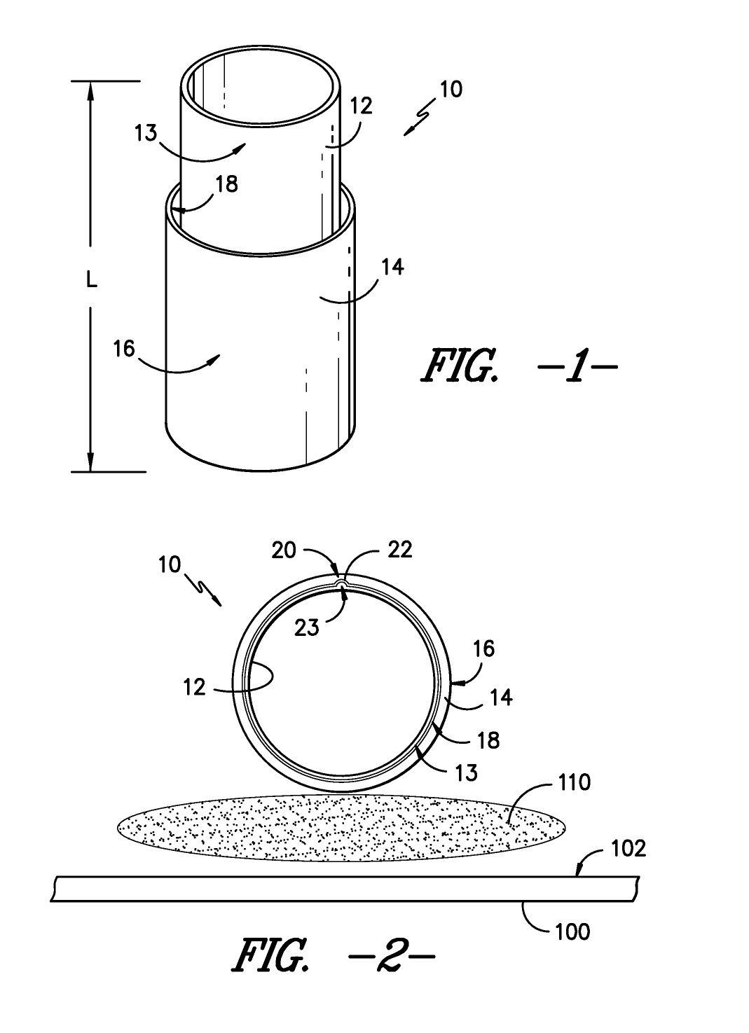

As shown in FIG. 1, the cylindrical sputtering target 10 generally includes a tubular member 12 having a length (L) in a longitudinal direction. The tubular member 12 defines a tube surface 13. The cylindrical sputtering target 10 also generally includes a source material 14 positioned about the tube surface 13 of the tubular member 12 and forming a sputtering surface 16 of the target 10.

The source material 14 also defines an inner surface 18 opposite of the sputtering surface 16. The inner surface 18 is non-bonded to the tube surface 13 of the tubular member 12. As used herein, the term “non-bonded” refers to the source material 14 being free from any attachment force between its inner surface 18 and the tube surface 13 (i.e., no welding, solder, adhesive, or other attachment material is present between the inner surface 18 of the source material 14 and the tube surface 13 of the tubular member 12).

Since the source material 14 is not bonded to the tubular member 12, thermal conduction therebetween may be inhibited, particularly in the relatively low vacuum pressures of the sputtering atmosphere (e.g., about 1 mTorr to about 50 mTorr) present during sputtering. Thus, the source material 14 becomes hot due to the plasma in the sputtering chamber and/or a radiative heat source within the sputtering chamber. For any substantially constant sputtering process (i.e., with a substantially constant magnetron power, sputtering pressure, and/or sputtering temperature), the source material 14 can reach a relatively stable sputtering temperature when the thermal energy absorbed along the sputtering surface 16 is substantially equal to the thermal energy radiated from the inner surface 18 of the source material 14 to the tube surface 13 of the tubular member 12. For example, the sputtering temperature of the source material 14 can be about 100° C. to about 1,000° C. depending on the particular sputtering parameters utilized.

Thus, the non-bonded cylindrical target 10 can present several distinct advantages over their bonded counterparts. For example, the non-bonded source material 14 can be sputtered with a reduction, or substantial elimination, of nodules formed in the target's sputtering surface 16. Thus, the non-bonded target 14 can be more uniformly sputtered during the deposition process and can lead to the formation of more uniform thin film layers (e.g., cadmium sulfide thin film layers, cadmium tin oxide layers, etc.), both on a single substrate and throughout the manufacturing process (i.e., from substrate to substrate).

According to one particular embodiment, the inner surface 18 of the source material 14 is mechanically engaged to the tube surface 13 of the tubular member 12. That is, at least one point of the inner surface 18 of the source material 14 can mechanically interact with the tube surface 13 of the tubular member 12 while remaining non-bonded therebetween. For example, in one embodiment, at least 90% of the surface area of the inner surface 18 of the source material 14 can be free from contact with the tube surface 13 of the tubular member 12 (e.g., at least 95%, such as about 95% to about 99.99%). Thus, thermal conduction between the source material 14 and the tubular member 12 can be minimized while still allowing the mechanical engagement therebetween.

The mechanical engagement between the inner surface 18 of the source material 14 and the tube surface 13 of the tubular member 12 allows for the rotation of the tubular member 12 and the source material 14 to be synchronized in terms of angular velocity. Thus, the tubular member 12 can be rotated, causing synchronized rotation of the source material 14 while leaving the tubular member 12 non-bonded to the source material 14.

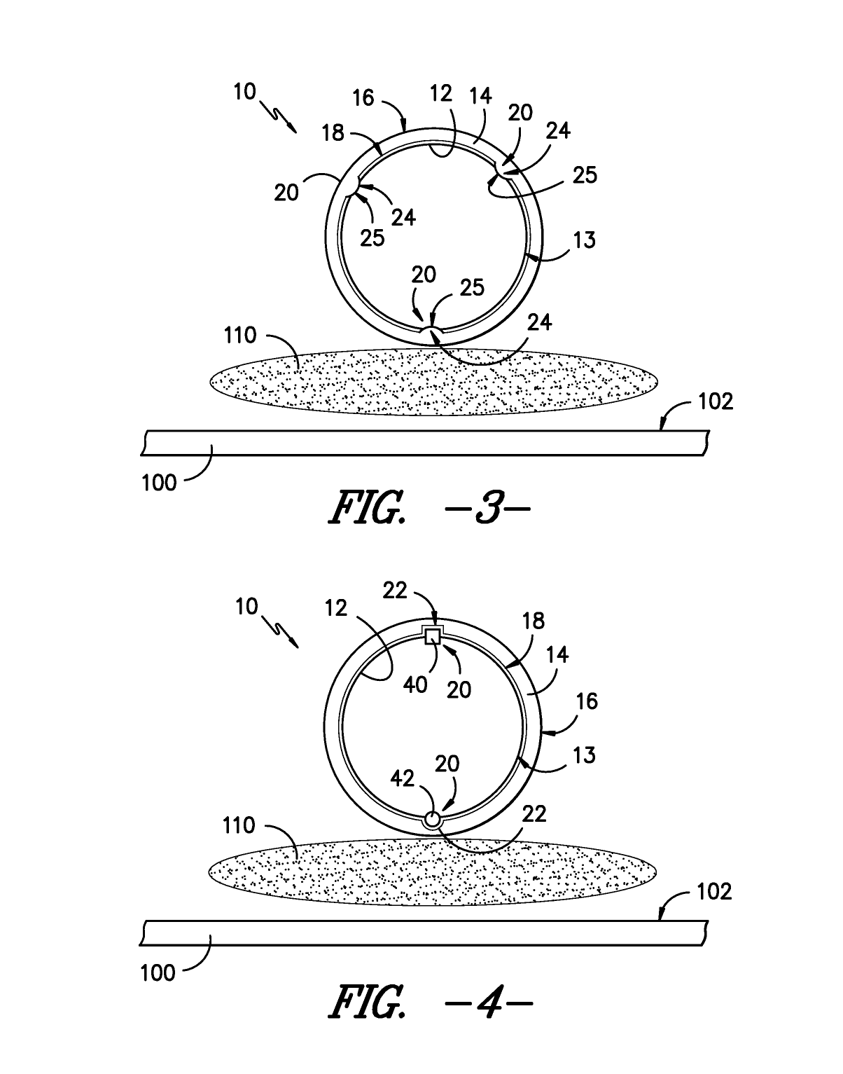

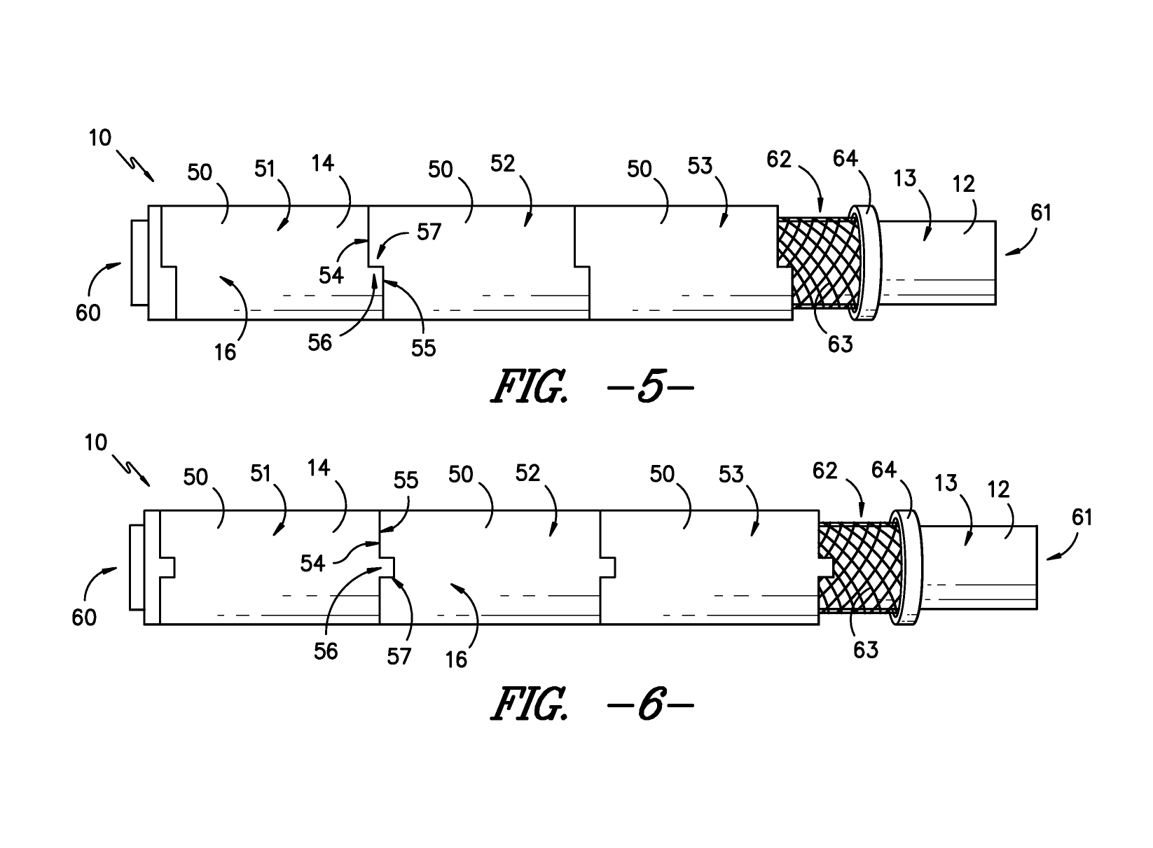

In one particular embodiment, the inner surface 18 of the source material 14 and the tube surface 13 of the tubular member 12 can be mechanically engaged to each other via at least one male/female connection (generally 20). Referring to FIG. 2, for instance, the inner surface 18 of the source material 14 defines a cavity 22 that is coupled to a protrusion 23 defined in the tube surface 13. Although shown as rounded, the protrusion 23 can define any suitable shape. For example, FIG. 4 shows another embodiment of the inner surface 18 of the source material 14 defines a cavity 22 that is coupled to a square protrusion 40 and a rounded protrusion 42 defined in the tube surface 13. As shown, the cavities 22 can have a shape configured to interact (e.g., substantially match) the protrusion 23.

In the alternative embodiment shown in FIG. 3, the inner surface 18 of the source material 14 defines a protrusion 24 that is coupled to a cavity 25 defined in the tube surface 13.

The source material 14, in one particular embodiment, defines at least one cylindrical ring 50. For example, the source material can include three or more cylindrical rings 50 stacked on each other. As shown in FIGS. 5-7, the use of three cylindrical rings (i.e., a first cylindrical ring 51, a second cylindrical ring 52, and a third cylindrical ring 53) is shown. Additional cylindrical rings can be similarly stacked on each other, as desired in a particular embodiment.

In general, each of the stacked cylindrical rings 50 are mechanically engaged to each other. That is, each cylindrical ring 50 is mechanically engaged at its end(s) to an adjacent cylindrical ring. Thus, the cylindrical rings 50 can be rotated in unison.

For explanation purposes, the mechanical interaction of adjacent cylindrical rings (e.g., in a stack of a plurality of cylindrical rings) is discussed with respect to a first cylindrical ring 51 directly stacked onto a second cylindrical ring 52, with the first cylindrical ring 51 mechanically engaged to the second cylindrical ring 52.

In one particular embodiment, a top surface 54 of the first cylindrical ring 51 is positioned adjacent to and mechanically engaged with a bottom surface 55 of the second cylindrical ring 52. For example, the top surface 54 of the first cylindrical ring 51 can define a protrusion 56 that couples to a cavity 57 defined in the bottom surface 55 of the second cylindrical ring 52. Alternatively, the top surface 54 of the first cylindrical ring 51 can define a cavity that couples to a protrusion defined in the bottom surface 55 of the second cylindrical ring 52.

The use of multiple cylindrical rings 50 allows for the rings 50 to have a size smaller than the entire length (L) of the tubular member 12 (as measured from a first end 60 to a second end 61). Thus, the source material 14 can be shaped more easily and less costly, when compared to forming a single piece.

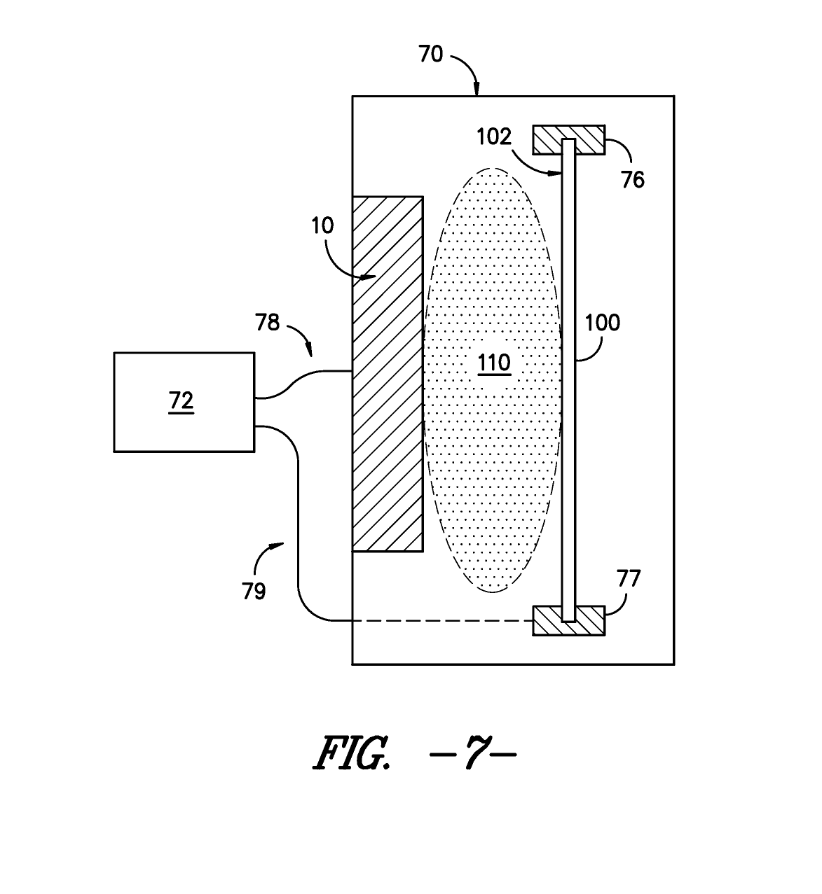

In particular embodiments, a biasing mechanism 62 is included in the cylindrical sputtering target 10. The biasing mechanism 62 is generally configured to force the cylindrical rings 50 together (e.g., to force the first cylindrical ring 51 into direct contact with the second cylindrical ring 52). As shown in FIGS. 5 and 6, the biasing mechanism 62 is a spring 63 attached to an end cap 64; however, any suitable biasing mechanism can be utilized. In one embodiment, gravity can be utilized as a biasing force without the need for any additional biasing mechanism, particularly in a vertical sputtering configuration.

The cylindrical target 10 can be utilized with any suitable sputtering process and/or apparatus. Sputtering deposition generally involves ejecting material from the target, which is the material source, by contacting the target with a plasma. The ejected material can then be deposited onto the substrate to form the film. DC sputtering generally involves applying a voltage to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. The pressure of the reactive atmosphere can be between about 1 mTorr and about 20 mTorr for magnetron sputtering. When metal atoms are released from the target upon application of the voltage, the metal atoms can react with the plasma and deposit onto the surface of the substrate. For example, when the atmosphere contains oxygen, the metal atoms released from the metal target can form a metallic oxide layer on the substrate. Conversely, RF sputtering generally involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere), and can have a relatively low sputtering pressure (e.g., about 1 mTorr and about 20 mTorr).

FIG. 7 shows a general schematic as a cross-sectional view of an exemplary DC sputtering chamber 70 according to one embodiment. A DC power source 72 is configured to control and supply DC power to the chamber 70. As shown, the DC power source applies a voltage to the cylindrical target 10 (serving as a cathode) to create a voltage potential between the target 10 and an anode formed by the chamber wall, such that the substrate 100 is in between the cathode and anode. The substrate 100 (e.g., a glass substrate) is held between top support 76 and bottom support 77 and is connected to the power supply 72 via wires 78 and 79, respectively. Generally, the substrate 100 is positioned within the sputtering chamber 70 such that thin film layer 102 is formed on the substrate 100 faces the target 10.

A plasma field 110 is created once the sputtering atmosphere is ignited, and is sustained in response to the voltage potential between the target 10 and the chamber wall acting as an anode. The voltage potential causes the plasma ions within the plasma field 110 to accelerate toward the target 10, causing atoms from the sputtering surface 14 of the target 10 to be ejected toward the substrate 100. As such, the target 10 acts as the source material for the formation of the thin film layer 102 on the substrate 100. The target 10 can be a metal target, such as elemental tin, cadmium, and/or zinc, or mixtures thereof. The sputtering atmosphere can contain oxygen gas, particularly when utilizing a metal target, oxygen particles of the plasma field 110 can react with the ejected target atoms to form the thin film layer 102 on the substrate 100. In other embodiment, the target 10 can be a ceramic target (e.g., including a mixture of metal(s) and oxygen).

During sputtering deposition, the cylindrical target 10 is rotated about its longitudinal axis as discussed above.

Although only a single DC power source 72 is shown, the voltage potential can be realized through the use of multiple power sources coupled together. Additionally, the exemplary sputtering chamber 70 is shown having a vertical orientation, although any other configuration can be utilized.

The presently provided methods and apparatus can be utilized in the formation of any film layer, particularly those suitable for inclusion in a photovoltaic thin film stack. For example, a transparent conductive oxide layer (e.g., formed from cadmium stannate), a resistive transparent buffer layer (e.g., formed from a zinc-tin oxide), and/or an n-type window layer formed from cadmium sulfide can be deposited using a cylindrical target 10 as described above. For example, the thin film layer(s) can be used during the formation of any cadmium telluride device that utilizes a cadmium telluride layer, such as in the cadmium telluride thin film photovoltaic device disclosed in U.S. Publication No. 2009/0194165 of Murphy, et al. titled “Ultra-high Current Density Cadmium Telluride Photovoltaic Modules.”

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

1. A cylindrical sputtering target, comprising:
a tubular member having a length in a longitudinal direction and defining a tube surface; and,
a source material positioned about the tube surface of the tubular member and forming a sputtering surface about the tubular member, wherein the source material defines an inner surface opposite of the sputtering surface and non-bonded to the tube surface of the tubular member, and wherein the inner surface of the source material is mechanically engaged to the tube surface of the tubular member,
wherein the source material comprises a first cylindrical ring directly stacked onto a second cylindrical ring, wherein the first cylindrical ring defines a top surface positioned adjacent to a bottom surface of the second cylindrical ring, and wherein the top surface of the first cylindrical ring is mechanically engaged to the bottom surface the second cylindrical ring, and wherein the top surface of the first cylindrical ring defines a protrusion or a cavity that couples to a cavity or protrusion, respectively, defined in the bottom surface of the second cylindrical ring.

2. The cylindrical sputtering target as in claim 1, wherein the inner surface of the source material defines a protrusion that couples to a cavity defined in the tube surface.

3. The cylindrical sputtering target as in claim 1, wherein the inner surface of the source material defines a cavity that couples to a protrusion defined in the tube surface.

4. The cylindrical sputtering target as in claim 1, wherein the source material defines a cylindrical ring.

5. (canceled)

6. The cylindrical sputtering target as in claim 1, wherein the source material comprises a three or more cylindrical rings stacked on each other.

7-8. (canceled)

9. The cylindrical sputtering target as in claim 1, wherein the top surface of the first cylindrical ring defines a protrusion that couples to a cavity defined in the bottom surface of the second cylindrical ring.

10. The cylindrical sputtering target as in claim 1, wherein the top surface of the first cylindrical ring defines a cavity that couples to a protrusion defined in the bottom surface of the second cylindrical ring.

11. The cylindrical sputtering target as in claim 1, wherein the inner surface of the source material defines a protrusion that couples to a cavity defined in the tube surface.

12. The cylindrical sputtering target as in claim 1, wherein the inner surface of the source material defines a cavity that couples to a protrusion defined in the tube surface.

13. The cylindrical sputtering target as in claim 1, further comprising:
a biasing mechanism configured to force the first cylindrical ring directly stacked onto a second cylindrical ring.

14. The cylindrical sputtering target as in claim 13, wherein the biasing mechanism comprises a spring.

15. The cylindrical sputtering target as in claim 1, wherein the source material comprises a plurality of first areas and a plurality of second areas, each first area comprising a first compound and each second area comprising a second compound that is different than the first compound.

16-20. (canceled)
